(19) United States
(12) Patent Application Publication
(10) Pub. No.: US 2026/0154480 A1
(43) Pub. Date: Jun. 4, 2026

(54) SYSTEM AND METHOD OF TRACKING DRILLING FLUID DATA

(71) Applicant: Baker Hughes Oilfield Operations LLC, Houston, TX (US)

(72) Inventors: Aswath Krishnan, Conroe, TX (US); Charles Thompson, Kingwood, TX (US); Jose Martinez, Spring, TX (US); Reza Ettehadi Osgouei, Spring, TX (US)

(21) Appl. No.: 18/967,038

(22) Filed: Dec. 3, 2024

(51) Int. Cl. G06F 30/28

(52) U.S. Cl. CPC G06F 30/28

(57) ABSTRACT

A tracking system for tracking a fluid. A memory storage device includes a first memory block. A processor assigns the first memory block to a first unit volume of a fluid, wherein the first memory block includes a field and first data stored in the field to represent a first state of the first unit volume. The processor modifies the first memory block to record a transaction that changes the first unit volume of the fluid from the first state to a second state, wherein modifying the first memory block includes recording a second data at the first memory block that represents the second state of the first unit volume. The processor reads the second data from the first memory block and performs an operation using the first unit volume in the second state based on the second data.

### BACKGROUND

In the resource recovery and fluid sequestration industries, drilling fluid is used to facilitate various operations. For example, a drilling operation includes circulating the drilling fluid downhole into a borehole through a drill string and uphole through an annulus between the drill string and a wall of the borehole. The drilling fluid prevents a drill bit from sticking, carries cuttings uphole and protects the borehole wall from collapsing. During drilling, the drilling fluid is exposed to various processes which alter the fluid's original composition, making it difficult to trace a characteristic of the fluid from its production to its final end use. Optimal use of the drilling fluid, however, requires tracking the characteristic. Accordingly, it is desirable to track drilling fluids through an entire process of a drilling operation.

### SUMMARY

Disclosed herein is a method of tracking a fluid, including assigning a first memory block to a first unit volume of the fluid, wherein the first memory block includes a field and first data stored in the field to represent a first state of the first unit volume, modifying the first memory block to record a transaction that changes the first unit volume from the first state to a second state, wherein modifying the first memory block includes recording a second data at the first memory block that represents the second state of the first unit volume, reading the second data from the first memory block, and performing an operation using the first unit volume in the second state based on the second data.

Also disclosed herein is a tracking system, including a memory storage device, and a processor configured to assign a first memory block in the memory storage device to a first unit volume of a fluid, wherein the first memory block includes a field and first data stored in the field to represent a first state of the first unit volume, modify the first memory block to record a transaction that changes the first unit volume of the fluid from the first state to a second state, wherein modifying the first memory block includes recording a second data at the first memory block that represents the second state of the first unit volume, read the second data from the first memory block, and perform an operation using the first unit volume in the second state based on the second data.

### BRIEF DESCRIPTION OF THE DRAWINGS

The following descriptions should not be considered limiting in any way. With reference to the accompanying drawings, like elements are numbered alike:

FIG. 1 shows a borehole system, in an illustrative embodiment;

FIG. 2 is a diagram illustrating a method for representing a volume of drilling fluid;

FIG. 3 is a diagram showing a unit volume of drilling fluid and a memory block that corresponds to the unit volume;

FIG. 4 is a diagram illustrating a change in a memory block due to a transaction;

FIG. 5 is a diagram illustrating a memory block transition representing a transportation transaction;

FIG. 6 is a diagram illustrating a memory block transition representing a mixing transaction;

FIG. 7 is a schematic diagram illustrative device for data input; and

FIG. 8 is a diagram of a fluid tracking system, in an illustrative embodiment.

### DETAILED DESCRIPTION

A detailed description of one or more embodiments of the disclosed apparatus and method are presented herein by way of exemplification and not limitation with reference to the Figures.

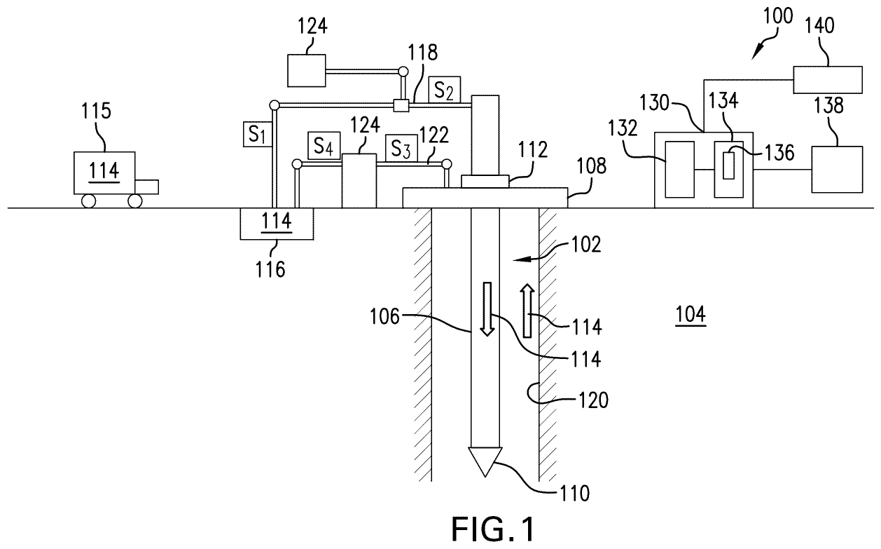

Referring to FIG. 1, a borehole system 100 is illustrated. The borehole system 100 comprises a borehole 102 in a subsurface formation 104. A drill string 106 extends into the borehole 102 from a platform 108 at the earth's surface. The drill string 106 includes a drill bit 110 at a bottom end. The drill bit 110 can be rotated either via a motor disposed within the drill string 106 or by rotation of the drill string 106 via a rotation table 112 at the platform 108.

Drilling mud or drilling fluid 114 is used to aid in the drilling process by, among others, removing cuttings from the borehole. The drilling fluid 114 can be shipped to the drilling site using a transportation vehicle 115, such as a truck, etc. and deposited in a mud pit 116 or placed in storage at the borehole system 100. The drilling fluid 114 is circulated from the mud pit 116 into the drill string 106 via an injection line 118. Chemical additives 117, such as tracer chemicals, etc. can be added to the drilling fluid 114 in the injection line 118. The drilling fluid 114 circulates downhole through a bore of the drill string 106 to exit the drill string at the drill bit 110. The drilling fluid 114 then flows uphole through an annulus between the drill string 106 and the wall 120 of the borehole 102. At the surface, the drilling fluid 114 is circulated back to the mud pit via a return line 122. The return line 122 passes through a solids removal unit 124 at which cuttings are removed from the drilling fluid 114. The cleaned fluids are then returned to the mud pit 116.

The drilling mud undergoes a series of transactions over its life time. A transaction indicates an operation that involves a change in a physical state (e.g., location, storage, shipping) and/or chemical state (e.g., chemical composition, viscosity, etc.) of the drilling fluid 114. Transactions include, but are not limited to, transportation of the drilling fluid to the drill site, addition of chemicals to the drilling fluid, dilution of the drilling fluid, loss of the drilling fluid downhole, solids remove treatment, mixing with other fluids, disposal of the fluid, etc. Additional transactions can indicate use of the drilling fluid in a sequestration process.

The methods disclosed herein track drilling fluid data from its origin to its end through its various transactions. The tracked data is used to adjust and/or optimize the treatment of the fluid and the utilization of the fluid. In particular, the overall carbon footprint can be tracked and a decision can be made to treat the fluid or to use a different fluid (e.g., a fluid with a lower carbon footprint) in order to reduce the overall carbon footprint for a process. Carbon footprint is calculated based on various inputs such as the chemical composition of the fluid, mixing/blending methods (e.g., use of electric pump vs. diesel engine pumps), shipping related carbon footprint data, the carbon footprint associated with storage, etc. The methods disclosed herein tracks the drilling fluid as a plurality of unit volumes of fluid. Each unit volume is assigned a memory block in a memory location and changes to the drilling fluid (e.g., losses, mixing, chemical addition, cost, etc.) are tracked at the memory block. Operations using the drilling fluid can be selected based on knowledge of the drilling fluid obtained from the memory block.

Various sensors S₁-S₄ can be located at different locations to track data regarding the drilling fluid, including the state properties of the drilling fluid. The data can be provided to a control unit 130 located at the surface. The control unit 130 includes a processor 132 and a memory storage device 134 having a programs 136 stored thereon. The memory storage device 134 further includes a memory space for performing the tracking methods disclosed herein. The results of the tracking can be sent to a display or monitor 138 for use by an operator to control the drilling operations. An input device 140 such as a keyboard can also be used to enter data. Alternatively, the control unit 130 can read data that tracks the fluid from the memory storage device and can control a drilling operation or operation on the drilling fluid based on the data. As a non-limiting list of examples, the control unit 130 can control the addition of a chemical additive to the drilling fluid, control a mixing operation, control a drilling operation, control a sequestration operation, fluid disposal, etc.

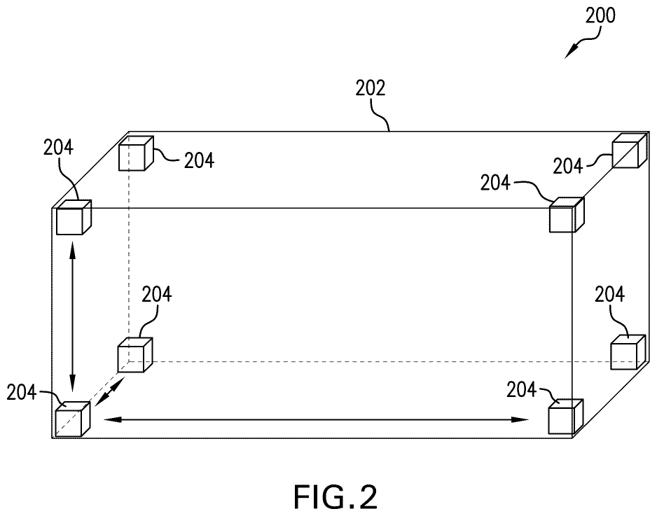

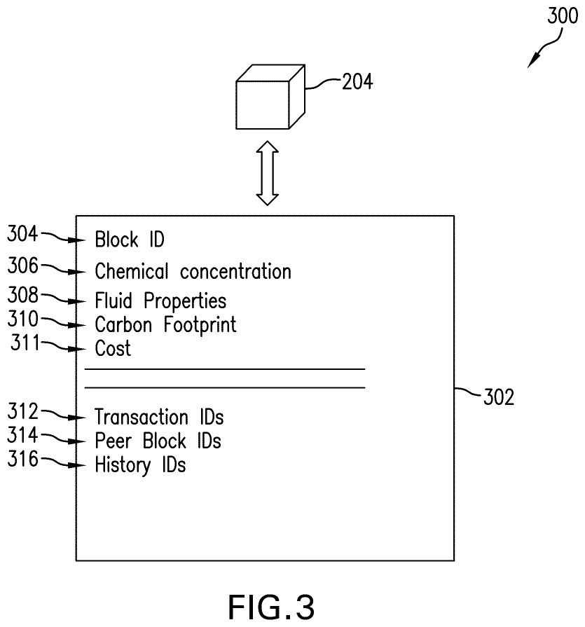

FIG. 2 is a diagram 200 illustrating a method for representing a volume of drilling fluid. The diagram 200 shows a bulk volume 202 of drilling fluid suitable for use in the borehole system. The bulk volume 202 can represent drilling fluid stored in a storage tank, in a truck, etc. or other suitable bulk volume. The methods disclosed herein tracks the bulk volume 202 as a plurality of unit volumes 204 of a suitable size, such as 1 m³, 2 m³, etc. Additionally, the size can be half units, such as 0.5 m³, etc. Each unit volume 204 is assigned to a memory block within the memory storage device 134 and characteristics of the unit volume 204 are tracked using the memory block, as shown in FIG. 3.

FIG. 3 is a diagram 300 showing a unit volume 204 of drilling fluid and a memory block 302 that corresponds to the unit volume. A memory block 302 is assigned for each unit volume 204. The memory block 302 includes various fields that identify the unit volume 204, including characteristics or properties of the unit volume, and a current state of the unit volume. Exemplary fields include a block identification number (block ID) 304 for identifying or labeling the unit volume, a chemical concentration 306 of the unit volume, fluid properties (e.g., viscosity, density, compressibility, temperature, etc.) 308 of the unit volume, carbon footprint data 310 of the unit volume, a cost 311 associated with the unit volume, a transaction identification data 312 to identify the current transaction of the unit volume, peer block identification numbers 314 which tracks memory blocks of other unit volumes associated with the unit volume, history block IDs 316 that tracks memory blocks representing a previous state (historical information) for the unit volume, etc.

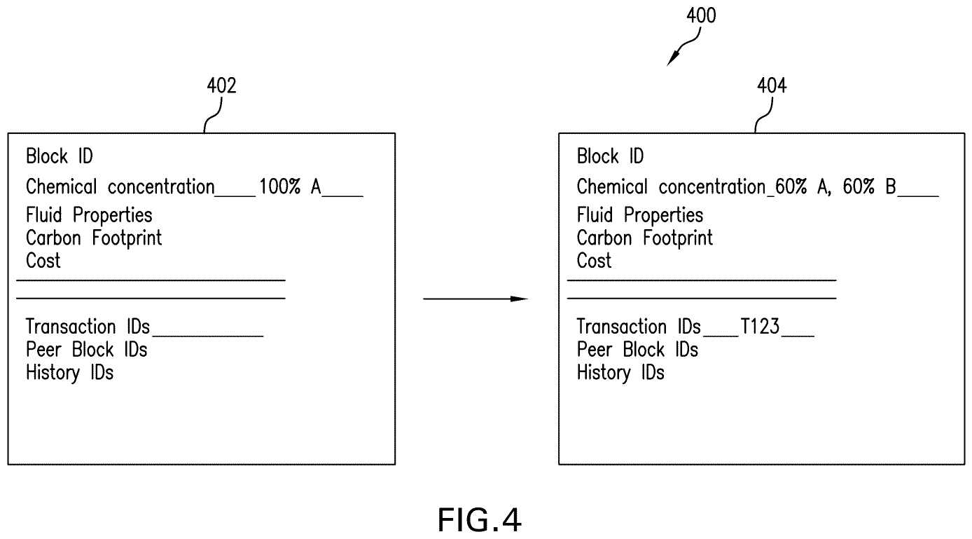

FIG. 4 is a diagram 400 illustrating a change in a memory block due to a transaction. For illustrative purposes, the transaction is a mixing transaction. The memory block initially corresponds to a unit volume having a concentration with 100% of chemical A. The mixing transaction involves blending chemical B into the volume. A memory block (in a first state 402) includes first data that record the unit volume in the initial state. After the transaction, the memory block (in a second state 404) is modified to record second data that includes a transaction ID (e.g., ‘T0123’) in the transaction field. Meanwhile, the second data is changed in the chemical composition field to reflect the new chemical composition (e.g., 50% A, 50% B). The transaction ID can also identify a time of the transaction, etc.

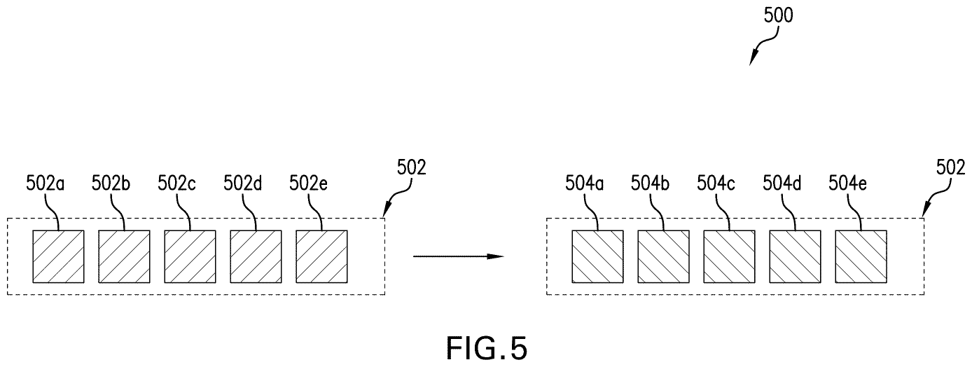

FIG. 5 is a diagram 500 illustrating a memory block transition representing a transportation transaction. Group 502 includes 5 memory blocks 502a-502e, each representing a unit volume of the drilling fluid. The group 502 represents 5 cubic meters of drilling fluid, with each memory block representing one cubic meter of drilling fluid. During the transportation transaction, data is written to each memory block to record the transportation. Thus, the memory blocks change to a different memory state 504a-504e to mirror the change in the state of the drilling fluid.

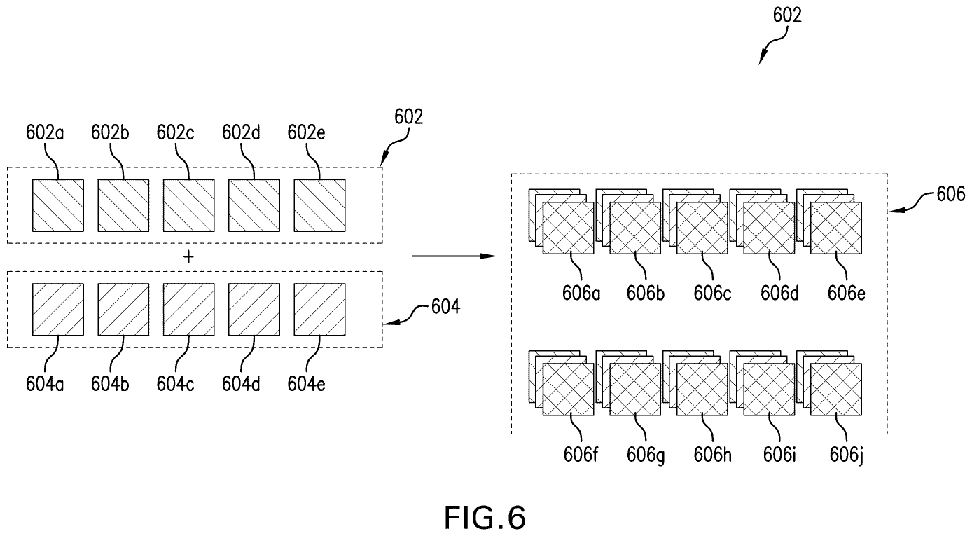

FIG. 6 is a diagram 600 illustrating a memory block transition representing a mixing transaction. A first group 602 of first memory blocks 602a-602e corresponds to a first volume of drilling fluid (e.g., drilling fluid A). A second group 604 of second memory blocks 604a-604e corresponds to a second volume of drilling fluid (e.g., drilling fluid B). The transaction includes mixing drilling fluid A and drilling fluid B in a selected mixing ratio. For illustrative purposes, the first group 602 represents five unit volumes of drilling fluid A and the second group 604 represents five unit volumes of drilling fluid B.

A third group 606 of third memory blocks 606a-603e is created in the memory storage device to represent the mixture. Due to the combination, the third group 606 represents 10 unit volumes of the blended mixture. Each third memory block (e.g., third memory block 606a) in the third group 606 is linked in memory to a corresponding first memory block (e.g., first memory block 602a) in the first group 602 and corresponding second memory block (e.g. second memory block 604a) in the second group 604. In an embodiment, third memory block 606a can store the memory addresses of first memory block 602a and second memory block 604a.

A loss of the drilling fluid, such as a downhole loss, can be recorded by either freeing up the memory space (removing the memory block) or by recording the loss in the memory block (e.g., volume=0, ⅛ m³, etc.).

In one embodiment, an operation can be controlled based on an associated cost of the drilling fluid. The drilling fluid has a cost associated with production, a cost associated with shipping, a cost associated with drilling, etc. Every cost transaction can be tracked in a field of the memory block. A decision can be made for the use of the drilling fluid based on the cost. For example, use of the drilling fluid can be halted once an accumulated cost exceeds a cost threshold. Alternatively, the drilling fluid can be transported to a desired location for subsequent uses based on accumulated cost, etc.

In another embodiment, an operation can be controlled based on a carbon footprint. If the carbon footprint is high (i.e., above a certain threshold), use of the drilling fluid can be stopped and the drilling fluid changed out for another fluid. Alternatively, the drilling fluid can be blended with another fluid to reduce the carbon footprint.

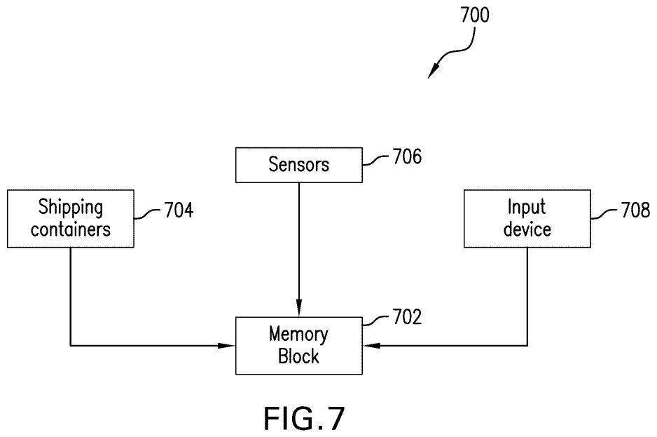

FIG. 7 is a schematic diagram 700 illustrating data input. Data can be entered into a memory block 702 using devices including, but not limited to, shipping locations 704, sensors 706 (such as sensors S₁-S₄) and input device(s) 708.

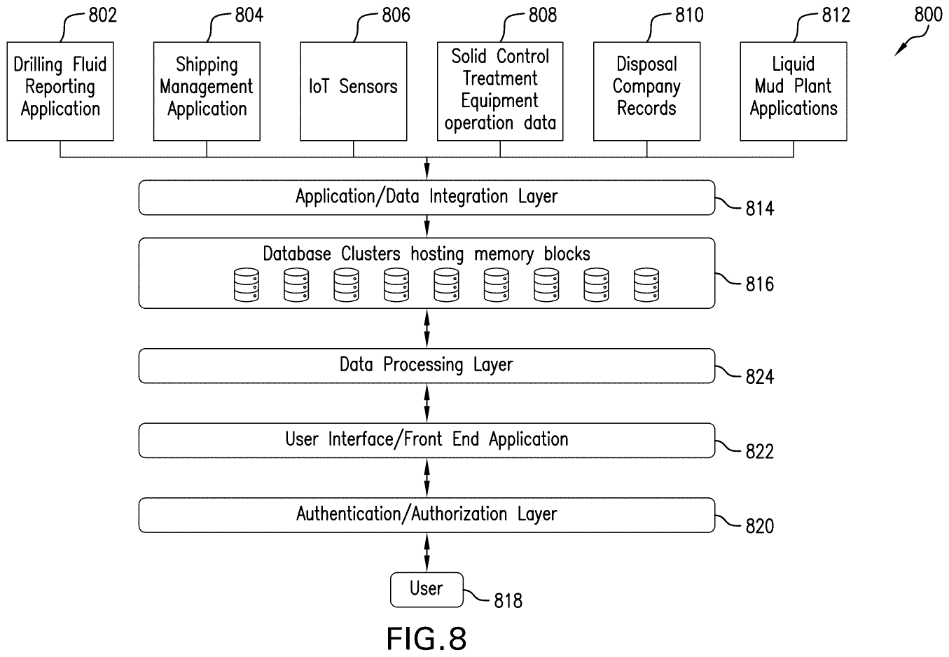

FIG. 8 is a diagram of a fluid tracking system 800, in an illustrative embodiment. Various data sources feed data to the memory blocks. Exemplary data sources include, but are not limited to, a drilling fluid reporting application 802, a shipping management application 804, Internet of Things (IoT) sensors 806, solids control treatment equipment operation data 808, disposal company records 810, and liquid mud applications 812. The various sources provide data to an application/data integration layer 802. The application/data integration layer 802 is responsible for collecting the fluid tracking data from the various sources.

A database cluster 814 hosts the memory blocks. The database cluster 812 can be a centralized database or a decentralized database. A user 816 accesses the database cluster 814 via an authentication layer 818, a user interface 820 and a data processing layer 820. The authentication layer 818 insures that only legitimate users are allowed to access the system. The user interface 820 enables the user to interact with the fluid tracking system. The user interface 820 is integrated into the data processing layer 822. The data processing layer 822 converts data and performs calculations to translate the data into a form understandable to the user 816.

Set forth below are some embodiments of the foregoing disclosure:

Embodiment 1. A method of tracking a fluid. A first memory block is assigned to a first unit volume of the fluid, wherein the first memory block includes a field and first data stored in the field to represent a first state of the first unit volume. The first memory block is modified to record a transaction that changes the first unit volume from the first state to a second state, wherein modifying the first memory block includes recording a second data at the first memory block that represents the second state of the first unit volume. The second data is read from the first memory block. An operation is performed using the first unit volume in the second state based on the second data.

Embodiment 2. The method of any prior embodiment, wherein the transaction comprises at least one of: (i) a dilution of the first unit volume; (ii) addition of a chemical additive to the first unit volume; (iii) losses from the first unit volume; (iv) solids removal treatment; (v) mixing the first unit volume with a second unit volume of the fluid; (vi) storage of the unit volume at a plant; (vii) transportation of the unit volume; (viii) return of the unit volume to a previous location; and (ix) disposal of the unit volume.

Embodiment 3. The method of any prior embodiment, wherein the transaction includes mixing the first unit volume with a unit second volume of the fluid, further comprising linking the first memory block and a second memory block representing the second unit volume to a third memory block to record the mixing.

Embodiment 4. The method of any prior embodiment, wherein performing the operation further comprises at least one of: (i) performing a drilling operation using the fluid, (ii) adding a chemical additive to the fluid; (iii) mixing the fluid; (iv) sequestering the fluid; (v) disposal of the fluid. ; and (vi) storing of the fluid.

Embodiment 5. The method any prior embodiment, wherein the first data and the second data include at least one of: (i) a composition of the first unit volume; (ii) a carbon footprint of the first unit volume; (iii) a fluid property of the first unit volume; and (iv) a cost of the first unit volume.

Embodiment 6. The method of any prior embodiment, further comprising determine carbon footprint based on at least one of: (i) chemical composition of the fluid; (ii) mixing methods used on the fluid; (iii) shipping related carbon footprint data; and (iv) the carbon footprint associated with storage.

Embodiment 7. The method of any prior embodiment, further comprising representing a loss of fluid from the first unit volume by at least one of: (i) registering the transaction at the memory block to indicate loss of fluid; and (ii) recording a value of the loss at the first memory block.

Embodiment 8. The method of any prior embodiment, further comprising dividing the fluid into a plurality of unit volumes, wherein the plurality of unit volumes includes the first unit volume, and assigning a plurality of memory blocks respectively to the plurality of unit volumes.

Embodiment 9. The method of any prior embodiment, wherein the fluid is a drilling fluid.

Embodiment 10. A tracking system including a memory storage device, and a processor configured to assign a first memory block in the memory storage device to a first unit volume of a fluid, wherein the first memory block includes a field and first data stored in the field to represent a first state of the first unit volume, modify the first memory block to record a transaction that changes the first unit volume of the fluid from the first state to a second state, wherein modifying the first memory block includes recording a second data at the first memory block that represents the second state of the first unit volume, read the second data from the first memory block, and perform an operation using the first unit volume in the second state based on the second data.

Embodiment 11. The tracking system of any prior embodiment, wherein the transaction comprises at least one of: (i) a dilution of the first unit volume; (ii) addition of a chemical additive to the first unit volume; (iii) losses from the first unit volume; (iv) solids removal treatment; (v) mixing the first unit volume with a second unit volume of the fluid; (vi) storage of the unit volume at a storage facility; (vii) transportation of the unit volume; (viii) return of the unit volume to a previous location; and (ix) disposal of the unit volume.

Embodiment 12. The tracking system of any prior embodiment, wherein the transaction includes mixing the first unit volume with a unit second volume of the fluid and the processor is further configured to link the first memory block and a second memory block representing the second unit volume to a third memory block to record the mixing.

Embodiment 13. The tracking system of any prior embodiment, further wherein the operation includes at least one of: (i) a drilling operation, (ii) addition of a chemical additive to the fluid; (iii) a mixing operation; (iv) a sequestration operation; (v) disposal of the fluid; and (vi) storing of the fluid.

Embodiment 14. The tracking system of any prior embodiment, wherein the first data and the second data include at least one of: (i) a composition of the first unit volume; (ii) a carbon footprint of the first unit volume; (iii) a fluid property of the first unit volume; and (iv) a cost of the first unit volume.

Embodiment 15. The tracking system of any prior embodiment, wherein the processor is further configured to determine the carbon footprint based on at least one of: (i) chemical composition of the fluid; (ii) mixing methods used on the fluid; (iii) shipping related carbon footprint data; and (iv) the carbon footprint associated with storage.

Embodiment 16. The tracking system of any prior embodiment, wherein the processor is further configured to represent a loss of fluid from the first unit volume by at least one of: (i) registering the transaction at the memory block to indicate loss of fluid; and (ii) recording a value of the loss at the first memory block.

Embodiment 17. The tracking system of any prior embodiment, wherein the processor is further configured to divide the fluid into a plurality of unit volumes, wherein the plurality of unit volumes includes the first unit volume, and assign a plurality of memory blocks in the memory storage device, respectively, to the plurality of unit volumes.

The use of the terms “a” and “an” and “the” and similar referents in the context of describing the invention (especially in the context of the following claims) are to be construed to cover both the singular and the plural, unless otherwise indicated herein or clearly contradicted by context. Further, it should be noted that the terms “first,” “second,” and the like herein do not denote any order, quantity, or importance, but rather are used to distinguish one element from another. The terms “about”, “substantially” and “generally” are intended to include the degree of error associated with measurement of the particular quantity based upon the equipment available at the time of filing the application. For example, “about” and/or “substantially” and/or “generally” can include a range of ±8% of a given value.

The teachings of the present disclosure may be used in a variety of well operations. These operations may involve using one or more treatment agents to treat a formation, the fluids resident in a formation, a borehole, and/or equipment in the borehole, such as production tubing. The treatment agents may be in the form of liquids, gases, solids, semi-solids, and mixtures thereof. Illustrative treatment agents include, but are not limited to, fracturing fluids, acids, steam, water, brine, anti-corrosion agents, cement, permeability modifiers, drilling muds, emulsifiers, demulsifiers, tracers, flow improvers etc. Illustrative well operations include, but are not limited to, hydraulic fracturing, stimulation, tracer injection, cleaning, acidizing, steam injection, water flooding, cementing, etc.

While the invention has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited.

What is claimed is:

1. A method of tracking a fluid, comprising:
assigning a first memory block to a first unit volume of the fluid, wherein the first memory block includes a field and first data stored in the field to represent a first state of the first unit volume;
modifying the first memory block to record a transaction that changes the first unit volume from the first state to a second state, wherein modifying the first memory block includes recording a second data at the first memory block that represents the second state of the first unit volume;
reading the second data from the first memory block; and
performing an operation using the first unit volume in the second state based on the second data.

2. The method of claim 1, wherein the transaction comprises at least one of: (i) a dilution of the first unit volume; (ii) addition of a chemical additive to the first unit volume; (iii) losses from the first unit volume; (iv) solids removal treatment; (v) mixing the first unit volume with a second unit volume of the fluid; (vi) storage of the unit volume at a plant; (vii) transportation of the unit volume; (viii) return of the unit volume to a previous location; and (ix) disposal of the unit volume.

3. The method of claim 1, wherein the transaction includes mixing the first unit volume with a unit second volume of the fluid, further comprising linking the first memory block and a second memory block representing the second unit volume to a third memory block to record the mixing.

4. The method of claim 1, wherein performing the operation further comprises at least one of: (i) performing a drilling operation using the fluid, (ii) adding a chemical additive to the fluid; (iii) mixing the fluid; (iv) sequestering the fluid; (v) disposal of the fluid. ; and (vi) storing of the fluid.

5. The method of claim 1, wherein the first data and the second data include at least one of: (i) a composition of the first unit volume; (ii) a carbon footprint of the first unit volume; (iii) a fluid property of the first unit volume; and (iv) a cost of the first unit volume.

6. The method of claim 5, further comprising determine carbon footprint based on at least one of: (i) chemical composition of the fluid; (ii) mixing methods used on the fluid; (iii) shipping related carbon footprint data; and (iv) the carbon footprint associated with storage.

7. The method of claim 1, further comprising representing a loss of fluid from the first unit volume by at least one of: (i) registering the transaction at the memory block to indicate loss of fluid; and (ii) recording a value of the loss at the first memory block.

8. The method of claim 1, further comprising dividing the fluid into a plurality of unit volumes, wherein the plurality of unit volumes includes the first unit volume, and assigning a plurality of memory blocks respectively to the plurality of unit volumes.

9. The method of claim 1, wherein the fluid is a drilling fluid.

10. A tracking system, comprising:
a memory storage device;
a processor configured to:
assign a first memory block in the memory storage device to a first unit volume of a fluid, wherein the first memory block includes a field and first data stored in the field to represent a first state of the first unit volume;
modify the first memory block to record a transaction that changes the first unit volume of the fluid from the first state to a second state, wherein modifying the first memory block includes recording a second data at the first memory block that represents the second state of the first unit volume;
read the second data from the first memory block; and
perform an operation using the first unit volume in the second state based on the second data.

11. The tracking system of claim 10, wherein the transaction comprises at least one of: (i) a dilution of the first unit volume; (ii) addition of a chemical additive to the first unit volume; (iii) losses from the first unit volume; (iv) solids removal treatment; (v) mixing the first unit volume with a second unit volume of the fluid; (vi) storage of the unit volume at a storage facility; (vii) transportation of the unit volume; (viii) return of the unit volume to a previous location; and (ix) disposal of the unit volume.

12. The tracking system of claim 10, wherein the transaction includes mixing the first unit volume with a unit second volume of the fluid and the processor is further configured to link the first memory block and a second memory block representing the second unit volume to a third memory block to record the mixing.

13. The tracking system of claim 10, further wherein the operation includes at least one of: (i) a drilling operation, (ii) addition of a chemical additive to the fluid; (iii) a mixing operation; (iv) a sequestration operation; (v) disposal of the fluid; and (vi) storing of the fluid.

14. The tracking system of claim 10, wherein the first data and the second data include at least one of: (i) a composition of the first unit volume; (ii) a carbon footprint of the first unit volume; (iii) a fluid property of the first unit volume; and (iv) a cost of the first unit volume.

15. The tracking system of claim 14, wherein the processor is further configured to determine the carbon footprint based on at least one of: (i) chemical composition of the fluid; (ii) mixing methods used on the fluid; (iii) shipping related carbon footprint data; and (iv) the carbon footprint associated with storage.

16. The tracking system of claim 10, wherein the processor is further configured to represent a loss of fluid from the first unit volume by at least one of: (i) registering the transaction at the memory block to indicate loss of fluid; and (ii) recording a value of the loss at the first memory block.

17. The tracking system of claim 10, wherein the processor is further configured to divide the fluid into a plurality of unit volumes, wherein the plurality of unit volumes includes the first unit volume, and assign a plurality of memory blocks in the memory storage device, respectively, to the plurality of unit volumes.
